(19) United States
(12) Patent Application Publication
(10) Pub. No.: US 2023/0400604 A1
(43) Pub. Date: Dec. 14, 2023

(54) COLOR CONVERSION STRUCTURE, DISPLAY APPARATUS, AND METHOD OF MANUFACTURING THE COLOR CONVERSION STRUCTURE

(71) Applicant: SAMSUNG ELECTRONICS CO., LTD., Suwon-si (KR)

(72) Inventors: Kyungwook HWANG, Suwon-si (KR); Dongho KIM, Suwon-si (KR); Junsik HWANG, Suwon-si (KR); Sanghoon SONG, Suwon-si (KR)

(73) Assignee: SAMSUNG ELECTRONICS CO., LTD., Suwon-si (KR)

(21) Appl. No.: 18/196,583

(22) Filed: May 12, 2023

(30) Foreign Application Priority Data
May 20, 2022 (KR) 10-2022-0062347

(51) Int. Cl. G02B 1/00; G02F 1/015; H01L 33/10; G02B 5/20; G02B 1/14; G02B 3/00

(52) U.S. Cl. CPC G02B 1/005; G02F 1/0151; H01L 33/10; G02B 2207/107; G02B 1/14; G02B 3/0037; G02B 5/206

(57) ABSTRACT

Disclosed are a color conversion structure, a display apparatus, and a method for manufacturing the color conversion structure. The color conversion structure includes a base, a photonic crystal structure provided on the base, and quantum dots included in the photonic crystal structure. The color conversion structure has a transferable structure.

### CROSS-REFERENCE TO RELATED APPLICATION

This application is based on and claims priority under 35 U.S.C. § 119 to Korean Patent Application No. 10-2022-0062347, filed on May 20, 2022, in the Korean Intellectual Property Office, the disclosure of which is incorporated by reference herein in its entirety.

### BACKGROUND

### 1. Field

The disclosure relates to a color conversion structure transferable to a substrate, a display apparatus including the color conversion structure, and a method of manufacturing the color conversion structure.

### 2. Description of the Related Art

Liquid crystal displays (LCDs) and organic light-emitting diode (OLED) displays are widely used as display apparatuses. Recently, there has been an increasing interest in techniques for manufacturing high-resolution display apparatuses using micro-semiconductor chips (micro-light-emitting diodes).

Display apparatuses employing micro-semiconductor chips are manufactured by using many techniques such as a technique for transferring micro-light-emitting devices having a micro-size to desired pixel positions of a display apparatus, a process of repairing micro-light-emitting devices, and a method of realizing desired colors.

### SUMMARY

Provided is a color conversion structure transferable to a substrate.

Provided is a display apparatus including the color conversion structure transferable to a substrate.

Provided is a method of manufacturing the color conversion structure transferable to a substrate.

Additional aspects will be set forth in part in the description which follows and, in part, will be apparent from the description, or may be learned by practice of the presented embodiments of the disclosure.

According to an aspect of the disclosure, there is provided a color conversion structure including: a base; a photonic crystal structure on the base; and a plurality of quantum dots provided in the photonic crystal structure.

The base may include a bank structure including a groove, and the photonic crystal structure is provided in the groove.

The color conversion structure may be configured in units of pixels and is transferrable.

The color conversion structure may further include a protection layer on the photonic crystal structure.

The protection layer may include a concave-convex structure.

The color conversion structure may further include a distributed Bragg reflection layer on the photonic crystal structure.

The color conversion structure may further include a distributed Bragg reflection layer on a bottom of the groove.

The photonic crystal structure may have a thickness less than a depth of the groove.

The photonic crystal structure may have a thickness of about 10 μm to about 15 μm.

The photonic crystal structure may include a stacked structure in which two or more material layers having different refractive indexes are alternately arranged.

The base may include a groove array having a grating shape, and the photonic crystal structure is provided in the groove array.

The base may include a groove, and wherein the photonic crystal structure may include: a first material layer provided in the groove; and a plurality of second material portions that are three-dimensionally arranged in the first material layer.

The first material layer may include a porous material, and the plurality of quantum dots are provided in the porous material.

The porous material may include nGaN.

The color conversion structure may further include a reflection layer on a lateral portion of the photonic crystal structure.

The color conversion structure may further include a window region provided on a surface of the photonic crystal structure, the window region configured to allow light to be incident on the photonic crystal structure.

The color conversion structure may further include a lens array is provided on a surface of the photonic crystal structure, the lens array being configured to focus light on to the photonic crystal structure.

According to another aspect of the disclosure, there is provided a display apparatus including: a display substrate; a plurality of micro-semiconductor chips provided on the display substrate and spaced apart from each other; and a plurality of color conversion structures on the plurality of micro-semiconductor chips, wherein each of the color conversion structures may include: a base, a photonic crystal structure on the base, and a plurality of quantum dots provided in the photonic crystal structure.

According to another aspect of the disclosure, there is provided a method of manufacturing a color conversion structure, the method including: forming a base on a substrate; forming a photonic crystal structure on the base; forming a plurality of quantum dots in the photonic crystal structure; etching the base and the photonic crystal structure in units of pixels; and removing the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a color conversion structure according to an example embodiment;

FIG. 2 is a graph illustrating the reflectance of a photo crystal structure and the intensity of light with respect to the wavelength of light from a semiconductor light-emitting device;

FIG. 3 is a graph illustrating the intensity of light and the refractive index of a photo crystal structure with respect to the thickness of the photo crystal structure when the wavelength of incident light is 450 nm;

FIG. 4 is a graph illustrating the intensity of light and the refractive index of a photo crystal structure according to the thickness of the photonic crystal structure when the wavelength of incident light is 500 nm;

FIG. 5 is a graph illustrating the intensity of light and the refractive index of a photo crystal structure according to the thickness of the photonic crystal structure when the wavelength of incident light is 600 nm;

FIG. 6 is a view illustrating an example in which a lens array is further provided on the color conversion structure shown in FIG. 1;

FIG. 7 is a view illustrating a color conversion structure according to another example embodiment;

FIG. 8 is a view illustrating an example of a photonic crystal structure employed in the color conversion structure shown in FIG. 7;

FIG. 9 is a view illustrating another example of the photonic crystal structure employed in the color conversion structure shown in FIG. 7;

FIG. 10 is a view illustrating a color conversion structure according to another example embodiment;

FIG. 11 is a view illustrating a photonic crystal structure employed in the color conversion structure shown in FIG. 10;

FIG. 12 is a view illustrating an example in which a base of the color conversion structure shown in FIG. 10 is modified;

FIG. 13 is a view illustrating an example in which the color conversion structure shown in FIG. 12 includes a photonic crystal structure having two layers;

FIG. 14 is a view illustrating a color conversion structure according to another embodiment;

FIG. 15A is a view illustrating an example in which a protection layer of a color conversion structure includes a distributed Bragg reflection layer according to an example embodiment;

FIG. 15B is a view illustrating an example in which a protection layer of a color conversion structure has a regular hole pattern structure according to an example embodiment;

FIG. 15C is a view illustrating an example in which a protection layer of a color conversion structure has an irregular hole pattern structure according to an example embodiment;

FIG. 15D is a view illustrating an example in which a concave-convex structure is provided on a protection layer of a color conversion structure according to an example embodiment;

FIG. 16 is a view illustrating an example in which a protection layer of a color conversion structure has a convex shape according to an example embodiment;

FIG. 17 is a view illustrating an example in which a groove of a color conversion structure has a concave curved shape according to an example embodiment;

FIGS. 18A to 18G are views illustrating a method of manufacturing color conversion structures according to an example embodiment;

FIGS. 19A to 19F are views illustrating a method of manufacturing color conversion structures according to another example embodiment;

FIGS. 20 and 21 are views illustrating a method of transferring color conversion structures to a transfer substrate according to an example embodiment;

FIGS. 22 to 26 are views illustrating a method of manufacturing a display apparatus according to an example embodiment;

FIGS. 27 to 30 are views illustrating a method of manufacturing a display apparatus according to another example embodiment;

FIG. 31 is a view illustrating an example of a transfer substrate for color conversion structures according to an example embodiment;

FIG. 32 is a view illustrating an example of a transfer substrate that is usable two or more times for transferring color conversion structures according to an example embodiment;

FIG. 33 is a view schematically illustrating a display apparatus according to an example embodiment;

FIG. 34 is a cross-sectional view of the display apparatus taken along line A-A of FIG. 33;

FIG. 35 is a plan view corresponding to FIG. 34;

FIG. 36 is a block diagram schematically illustrating an electronic device according to an example embodiment;

FIG. 37 is a view illustrating an example in which a display apparatus is applied to a mobile device according to an example embodiment;

FIG. 38 is a view illustrating an example in which a display apparatus is applied to a vehicular display apparatus according to an example embodiment;

FIG. 39 is a view illustrating an example in which a display apparatus is applied to augmented reality glasses according to an example embodiment;

FIG. 40 is a view illustrating an example in which a display apparatus is applied to signage according to an example embodiment; and

FIG. 41 is a view illustrating an example in which a display apparatus is applied to a wearable display according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, color conversion structures, display apparatuses, and methods of manufacturing color conversion structures will be described according to various embodiments with reference to the accompanying drawings. In the drawings, like reference numbers refer to like elements, and the size of each element may be exaggerated for clarity of illustration. It will be understood that although the terms “first,” “second,” etc. may be used herein to describe various components, these components should not be limited by these terms. These terms are only used to distinguish one element from another.

As used herein, singular forms may include plural forms as well unless the context clearly indicates otherwise. It will be further understood that the terms “comprises,” “comprising,” “includes,” and/or “including” used herein specify the presence of stated features or elements, but do not preclude the presence or addition of one or more other features or elements. In the drawings, the size or thickness of each element may be exaggerated for clarity of illustration. Furthermore, it will be understood that when a material layer is referred to as being “on” or “above” a substrate or another layer, it can be directly on the substrate or the other layer, or intervening layers may also be present. Furthermore, in the following embodiments, a material included in each layer is an example, and another material may be used in addition to or instead of the material.

In the disclosure, terms such as “unit” or “module” may be used to denote a unit that has at least one function or operation and is implemented with hardware, software, or a combination of hardware and software.

Specific executions described herein are merely examples and do not limit the scope of the inventive concept in any way. For simplicity of description, other functional aspects of conventional electronic configurations, control systems, software and the systems may be omitted. Furthermore, line connections or connection members between elements depicted in the drawings represent functional connections and/or physical or circuit connections by way of example, and in actual applications, they may be replaced or embodied as various additional functional connections, physical connections or circuit connections.

An element referred to with the definite article or a demonstrative pronoun may be construed as the element or the elements even though it has a singular form.

Operations of a method may be performed in appropriate order unless explicitly described in terms of order or described to the contrary. In addition, examples or exemplary terms (for example, “such as” and “etc.”) are used for the purpose of description and are not intended to limit the scope of the inventive concept unless defined by the claims.

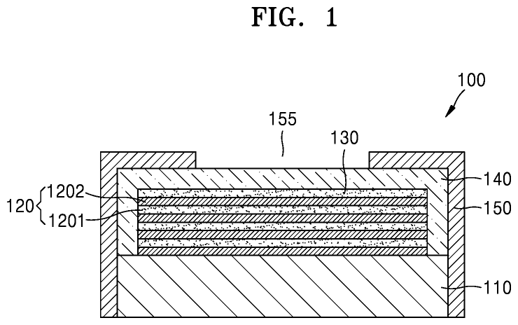

FIG. 1 illustrates a color conversion structure 100 according to an example embodiment.

The color conversion structure 100 may include a base 110, a photonic crystal structure 120 provided on the base 110, and quantum dots 130 provided in the photonic crystal structure 120.

The base 110 may include, for example, SiO₂, SiN, or GaN. The base 110 may be configured to transfer the color conversion structure 100 to a substrate. For example, the base 110 may be a film structure. Alternatively, the base 110 may be a bank structure. The base 110 will be further described below in detail. The color conversion structure 100 may be formed in units of pixels or sub-pixels for being transferred to a substrate. A pixel unit or a sub-pixel unit may refer to a minimum unit for displaying a color in a display apparatus.

The photonic crystal structure 120 may have a structure in which two or more materials having different refractive indexes are periodically arranged. The photonic crystal structure 120 may have a one-dimensional periodic arrangement, a two-dimensional periodic arrangement, or a three-dimensional periodic arrangement. For example, the photonic crystal structure 120 may have a structure in which a first layer 1201 having a first refractive index and a second layer 1202 having a second refractive index different from the first refractive index are alternately stacked. The first layer 1201 and the second layer 1202 may be stacked parallel to the base 110. Here, a structure in which two layers having different refractive indexes are alternately arranged has been described. However, the disclosure is not limited thereto, and as such, according to another example embodiment, a structure in which three layers respectively having a first refractive index, a second refractive index, and a third refractive index are alternately arranged may be provided. According to yet another example embodiment, a structure in which four or more layers, each having a different refractive index, are alternately arranged may also be possible. The optical path and reflectivity of the photonic crystal structure 120 may vary depending on the thicknesses and refractive indexes of the first layer 1201 and the second layer 1202.

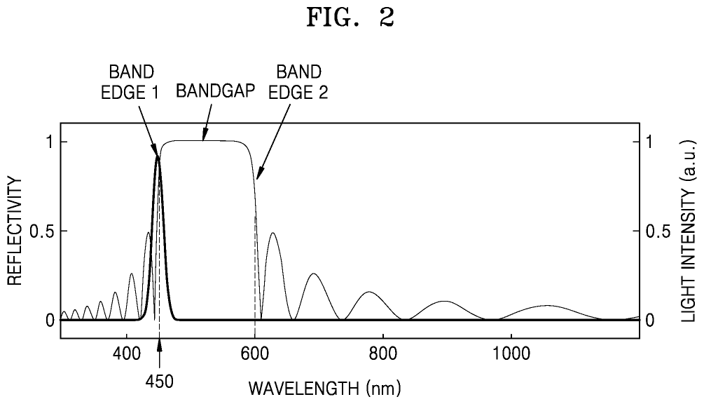

FIG. 2 shows the reflectivity of the photonic crystal structure 120 and light intensity with respect to the wavelength of light from a semiconductor light-emitting device. The photonic crystal structure 120 may have a relatively high reflectivity in a certain wavelength band. The reflectivity of the photonic crystal structure 120 sharply decreases at edges (band edge 1 and band edge 2) of a wavelength band (bandgap) in which the photonic crystal structure 120 has the greatest reflectivity. When incident light is adjusted such that the wavelength of the incident light corresponds to the wavelength at band edge 1 or band edge 2, an E-field may be amplified in the photonic crystal structure 120. For example, referring to FIG. 2, the wavelength at band edge 1 is about 450 nm, and the wavelength at band edge 2 is about 600 nm.

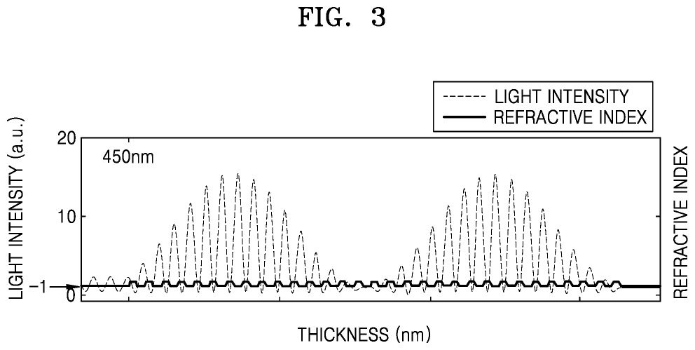

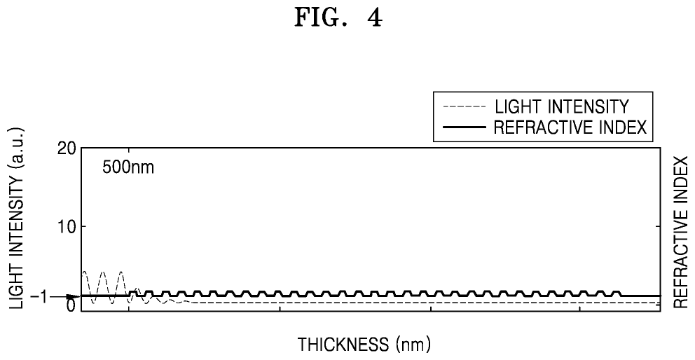

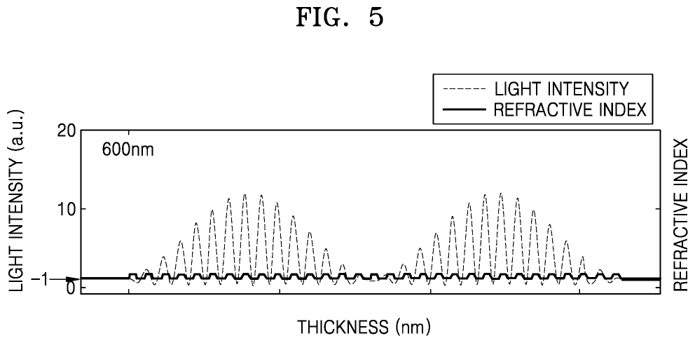

FIG. 3 shows light intensity and the refractive index of the photonic crystal structure 120 having the bandgap shown in FIG. 2 with respect to the thickness of the photonic crystal structure 120 when the wavelength of incident light is 450 nm. In FIG. 3, the solid line shows information the refractive index of the photonic crystal structure 120 with respect to the thickness of the photonic crystal structure 120. In addition, the dashed line shows light intensity inside the photonic crystal structure 120 with respect to the thickness of the photonic crystal structure 120. FIG. 4 shows light intensity and the refractive index of the photonic crystal structure 120 with respect to the thickness of the photonic crystal structure 120 when the wavelength of incident light is 500 nm. FIG. 5 shows light intensity and the refractive index of the photonic crystal structure 120 with respect to the thickness of the photonic crystal structure 120 when the wavelength of incident light is 600 nm. Here, the photonic crystal structure 120 has a structure in which 30 pairs of layers respectively having a refractive index (first refractive index) of 1 and a refractive index (second refractive index) of 1.5 are alternately stacked. FIGS. 3 to 5 show that the intensity of light having a wavelength of 450 nm corresponding to band edge 1 is amplified, the intensity of light having a wavelength of 500 nm included in the bandgap is not amplified, and the intensity of light having a wavelength of 600 nm corresponding to band edge 2 is amplified. That is, when the band edges of the photonic crystal structure 120 are designed according to the wavelength of incident light, the incident light may be amplified inside the photonic crystal structure 120, and thus color-converted light may be amplified.

Referring to FIG. 1, the quantum dots 130 may be included in the photonic crystal structure 120. For example, the quantum dots 130 may be distributed in at least one of the first layer 1201 or the second layer 1202. That is, according to an example embodiment, the quantum dots 130 may be distributed in one of the first layer 1201 or the second layer 1202. According to another example embodiment, the quantum dots 130 may be distributed in both of the first layer 1201 and the second layer 1202. The quantum dots 130 may be an inorganic material having a size of several nanometers (nm) and an energy bandgap in a specific wavelength band such that when the quantum dots 130 absorb light having an energy level greater than the energy bandgap, the quantum dots 130 may emit light at a different wavelength, thereby performing color conversion. Because the quantum dots 130 have a narrow emission wavelength band, the quantum dots 130 may improve the color reproducibility of a display apparatus.

The quantum dots 130 may have a core-shell structure having a core portion and a shell portion, or may have a particle structure having no shell. The core-shell structure may have a single-shell structure or a multi-shell structure such as a double-shell structure.

The quantum dots 130 may include a Group II-VI semiconductor, a Group III-V semiconductor, a group IV-VI semiconductor, a group IV semiconductor, and/or graphene quantum dots. The quantum dots 130 may include, for example, Cd, Se, Zn, S and/or InP, and each of the quantum dots 130 may have a diameter of several tens of nanometers (nm) or less, for example, a diameter of about 10 nm or less. When excited by blue light, the quantum dots 130 may emit green light or red light depending on the material or size of the quantum dots 130.

According to an example embodiment, the color conversion structure 100 may further include a protection layer 140 and a reflection layer 150. According to an example embodiment, the protection layer 140 may surround the photonic crystal structure 120. The protection layer 140 may be provided on upper and lateral surfaces of the photonic crystal structure 120. The protection layer 140 may include a light-transmitting material such that light emitted from the quantum dots 130 may pass through the protection layer 140. The protection layer 140 may include at least one selected from GaN, SiO₂, AL₂O₃, TiO₂, glass, spin-on-glass (SOG), SiN, and polymethyl methacrylate (PMMA). The protection layer 140 may protect the quantum dots 130 from external agents. Because the quantum dots 130 are vulnerable to moisture, the protection layer 140 may be provided on the photonic crystal structure 120 to improve reliability and increase price competitiveness by reducing the consumption of the quantum dots 130.

In addition, the protection layer 140 may have greater roughness and surface energy than the surface of the photonic crystal structure 120. Accordingly, when the color conversion structure 100 is transferred to a transfer substrate by a wet transfer method, self-transfer may be possible by a surface energy difference. Moreover, because the color conversion structure 100 is formed in a film shape in units of pixels, the color conversion structure 100 may be wet transferred to a transfer substrate.

Green and red micro-semiconductor chips used for micro-semiconductor chip displays have poor light-emitting efficiency but are expensive compared with blue micro-semiconductor chips used for micro-semiconductor chip displays. Therefore, when blue light emitted from blue micro-semiconductor chips are converted into green light or red light by using color conversion structures to display color images, light-emitting efficiency may be increased, and manufacturing costs may be reduced.

According to example embodiments, the color conversion structure 100 may improve the reliability of the quantum dots 130 and the efficiency of light conversion, and may be transferable to a micro-semiconductor chip display substrate.

In addition, when the thickness of the photonic crystal structure 120 including the quantum dots 130 is equal to or greater than a reference value, sufficient light conversion efficiency may be obtained. The reason for this improvement is that when the photonic crystal structure 120 is not sufficiently thick, excitation light leaks. In addition, as the thickness of the photonic crystal structure 120 increases, the intensity of converted light may increase, and the intensity of excitation light may decrease. For example, the photonic crystal structure 120 may have a thickness of about 10 μm to about 15 μm, and in this case, it may be possible to secure sufficient light conversion efficiency, reduce leakage of excitation light, and prevent a decrease in the intensity of excitation light. The thickness of the color conversion structure 100 may be adjusted to be within the above-mentioned range by using the photonic crystal structure 120.

According to an example embodiment, the reflection layer 150 may be further provided on a sidewall of the photonic crystal structure 120. The reflection layer 150 reflects light emitted from the photonic crystal structure 120 in inward directions, thereby reducing leakage of light in lateral directions or undesired directions of the color conversion structure 100. For example, the reflection layer 150 may increase a color conversion rate by increasing internal reflection of excitation blue light and may prevent interference of light between adjacent sub-pixel regions. The reflection layer 150 may be provided on the photonic crystal structure 120 or the protection layer 140. In addition, the reflection layer 150 may extend to a sidewall of the base 110. The reflection layer 150 may include, but is not limited to, Ag, Au, Pt, Ni, Cr, and/or Al.

According to an example embodiment, a window region 155 may be provided to allow light to enter the photonic crystal structure 120. The reflection layer 150 may not be provided in the window region 155. For example, the window region 155 may be provided on a surface of the photonic crystal structure 120 in a limited region in which the reflection layer 150 is not provided. The reflection layer 150 may be provided on a lateral portion of the photonic crystal structure 120, or may be provided on the lateral portion of the photonic crystal structure 120 and a portion of the upper side of the photonic crystal structure 120. Alternatively, the reflection layer 150 may be provided on a lateral portion of the protection layer 140 and a portion of the upper side of the protection layer 140.

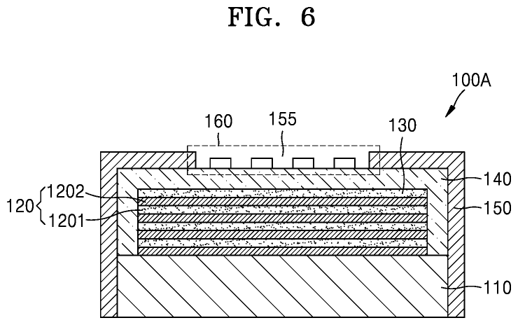

FIG. 6 illustrates an example in which a color conversion structure 100A further includes a lens array 160 compared with the color conversion structure 100 shown in FIG. 1. In FIGS. 1 and 6, like reference numerals denote elements having substantially the same functions and configurations, and thus overlapping descriptions thereof will be omitted. The lens array 160 may be provided in a window region 155 of the color conversion structure 100A. The lens array 160 may include, for example, a flat lens structure. When light is incident on the color conversion structure 100A, the lens array 160 may receive the light within a given angular range and focus the light onto the photonic crystal structure 120. That is, the lens array 160 may increase the optical efficiency of a photonic crystal structure 120 by increasing the fraction of light perpendicularly incident on the color conversion structure 100A.

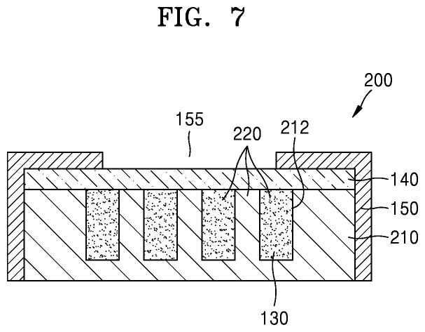

FIG. 7 illustrates a color conversion structure 200 according to another example embodiment.

In FIGS. 1 and 7, like reference numerals denote like elements, and thus overlapping descriptions thereof will be omitted.

According to an example embodiment, the color conversion structure 200 may include a base 210, and a photonic crystal structure 220. According to an example embodiment, the base 210 of the color conversion structure 200 includes a groove array 212, and a photonic crystal structure 220 may be provided in the groove array 212. According to an example embodiment, the groove array 212 may have a grating shape. According to an example embodiment, the photonic crystal structure 220 may have a structure in which materials having different refractive indexes are periodically arranged and coupled to the base 210. The photonic crystal structure 220 may have a structure in which a material forming the base 210 and a material forming the photonic crystal structure 220 are alternately arranged. In addition, quantum dots 130 may be distributed in a material of the photonic crystal structure 220.

For example, the photonic crystal structure 220 may include a structure in which the quantum dots 130 are embedded in a porous material of the photonic crystal structure 220. The porous material of the photonic crystal structure 220 may include nGaN, and the base 210 may include uGaN. The porous material may be formed by etching nGaN using an electrochemical etching method. When the porous material is immersed in a liquid containing the quantum dots 130, the quantum dots 130 may be embedded into the porous material. The quantum dots 130 embedded in the porous material may increase the scattering of light entering the porous material, and thus the efficiency of color conversion may be increased. When the color conversion structure 200 has a high color conversion efficiency, the photonic crystal structure 220 may have a relatively small thickness, and leakage of non-converted blue light may be reduced, making it possible to express highly pure colors. A protection layer 140 may be provided on the photonic crystal structure 220, and a reflection layer 150 may be provided on a sidewall of the base 210.

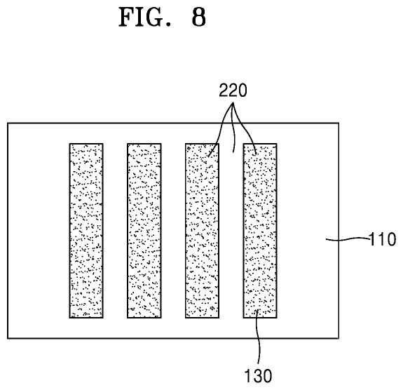

FIG. 8 illustrates an example of the photonic crystal structure 220. The photonic crystal structure 220 may include structures arranged in a line in the base 210. For example, the photonic crystal structure 220 may include a plurality of photonic crystal regions arranged adjacent to each other in a first direction.

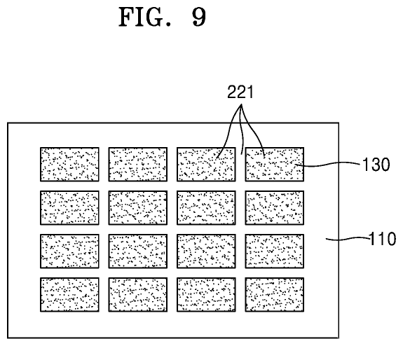

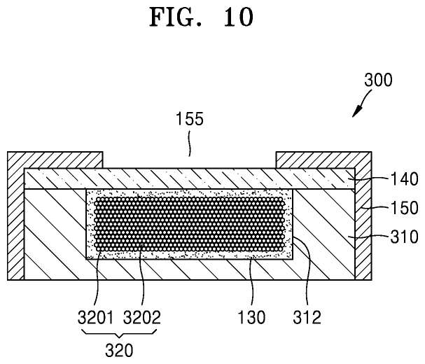

FIG. 9 illustrates a photonic crystal structure 221 according to another example. The photonic crystal structure 221 may include structures arranged in a two-dimensional matrix form in the base 210. For example, the photonic crystal structure 220 may include a plurality of photonic crystal regions arranged adjacent to each other in a first direction and a second direction.

FIG. 10 illustrates a color conversion structure 300 according to another example embodiment.

According to an example embodiment, the color conversion structure 300 may include a base 310, a photonic crystal structure 320 provided in the base 310, and quantum dots 130 provided in the photonic crystal structure 320. In FIGS. 1 and 10, like reference numeral denote elements having substantially the same functions and configurations, and thus overlapping descriptions thereof will be omitted.

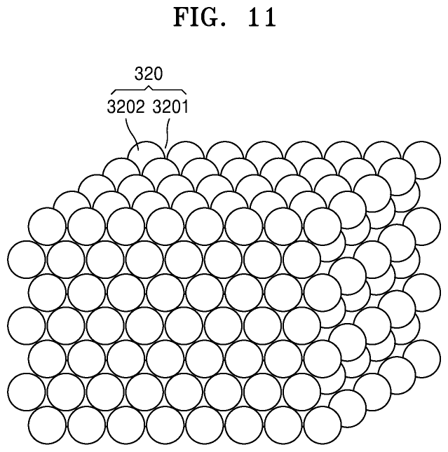

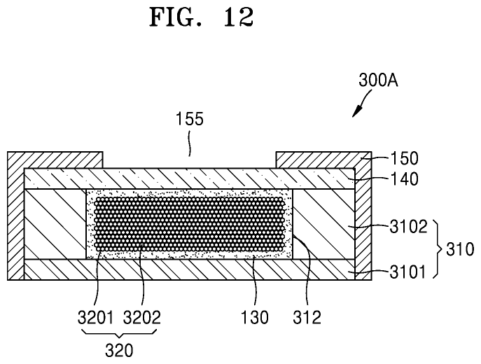

The base 310 may include a bank structure including a groove 312. The photonic crystal structure 320 may be provided in the groove 312. The base 310 may include an etchable material such as GaN, SiO₂, TiO₂, SiN, PMMA, or a photoresist. The thickness of the quantum dot layer for color conversion may be guaranteed depending on the depth of the groove 312. The photonic crystal structure 320 may have a three-dimensional periodic arrangement structure. Referring to FIG. 11, the photonic crystal structure 320 may include a first material layer 3201 and second material portions 3202 that are three-dimensionally arranged in the first material layer 3201. The first material layer 3201 may include a photoresist. The second material portions 3202 may have a spherical shape. The second material portions 3202 may include air voids or nano spheres. The quantum dots 130 may be distributed in the first material layer 3201.

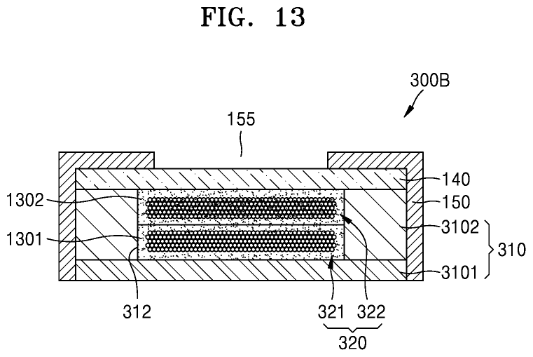

FIG. 12 illustrates a color conversion structure 300A having a modified base 310 compared with the color conversion structure 300 shown in FIG. 10. In FIGS. 10 and 12, like reference numerals denote like elements, and thus overlapping descriptions thereof will be omitted.

According to an example embodiment, the base 310 of the color converting structure 300A may include a bottom layer 3101 and a sidewall 3102. The base 310 shown in FIG. 10 has a one-piece structure, whereas the base 310 shown in FIG. 12 include separate portions, that is, the bottom layer 3101 and the sidewall 3102. The bottom layer 3101 and the sidewall 3102 may include different materials. However, the disclosure is not limited thereto, and as such, according to another example embodiment, the bottom layer 3101 and the sidewall 3102 may include the same material. A photonic crystal structure 320 is surrounded by the bottom layer 3101 and the sidewall 3102.

FIG. 13 illustrates an example in which a color conversion structure 300B has a modified photonic crystal structure 320 compared with the color conversion structure 300A shown in FIG. 12. In FIGS. 12 and 13, like reference numerals denote like elements, and thus overlapping descriptions thereof will be omitted.

According to an example embodiment, the photonic crystal structure 320 of the color conversion structure 300B may include a first photonic crystal structure 321 and a second photonic crystal structure 322. For example, the first photonic crystal structure 321 may include first quantum dots 1301 configured to convert the wavelength of incident light into a first wavelength, for example, a red wavelength. For example, the second photonic crystal structure 322 may include second quantum dots 1302 configured to convert the wavelength of incident light into a second wavelength, for example, a green wavelength. Because the photonic crystal structure 320 includes two layers as described above, the number of sub-pixels in each pixel may be reduced, and the size of a display apparatus may be reduced.

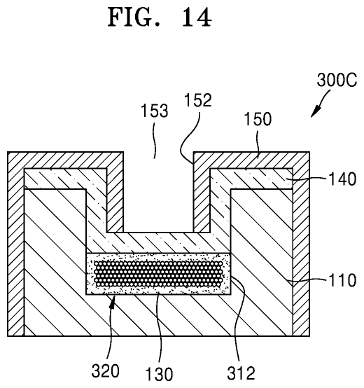

FIG. 14 illustrates a color conversion structure 300C having a modified structure compared with the color conversion structure 300 shown in FIG. 10. In FIGS. 10 and 14, like reference numerals denote like elements, and thus overlapping descriptions thereof will be omitted.

FIG. 14 illustrates an example in which a color conversion structure 300C includes a photonic crystal structure 320 having a thickness less than the depth of a groove 312 compared with the color conversion structure 300 shown in FIG. 10. According to an example embodiment, the photonic crystal structure 320 is filled only to a partial depth of a groove 312, and a reflection layer 150 may be provided on a sidewall and an upper portion of a base 310 and may further include an extension 152 extending to the inside of the groove 312. An opening 153 surrounded by the extension 152 may be defined. A micro-semiconductor chip (described later) may be accommodated in the opening 153.

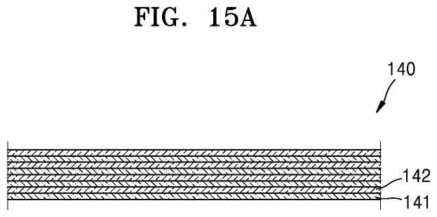

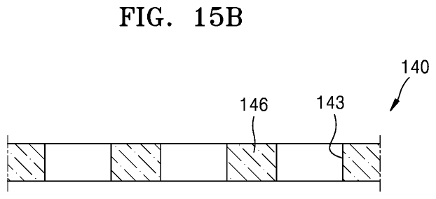

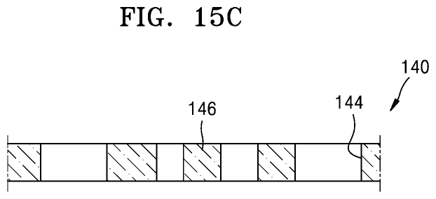

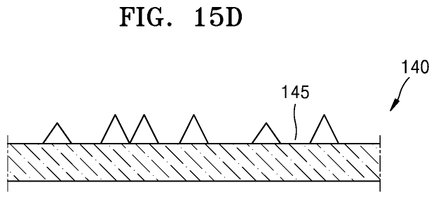

FIGS. 15A to 15D illustrate various examples of the protection layer.

Referring to FIG. 15A, the protection layer 140 may include a distributed Bragg reflection layer in which a first layer 1401 having a first refractive index and a second layer 1402 having a second refractive index are alternately arranged. The wavelength of reflected light may be determined depending on the thicknesses and materials of the first layer 141 and the second layer 142. When the protection layer 140 includes the distributed Bragg reflection layer, a color of light that is converted by the quantum dots 130 of the photonic crystal structure 320 may pass through the protection layer 140, and the other colors of the light may be recycled as being reflected by the protection layer 140, thereby increasing a color conversion ratio.

Referring to FIG. 15B, the protection layer 140 may include a plurality of holes 143 and a pattern 146 in which the holes 143 are regularly arranged.

Referring to FIG. 15C, the protection layer 140 may include a plurality of holes 144 and a pattern 146 in which the holes 144 are irregularly arranged. As described above, an engraved or embossed pattern may be formed on the protection layer 140 to increase the efficiency of extracting converted light and effectively prevent a light trapping phenomenon. The protection layer 140 may include a two-dimensional photonic crystal structure or a meta-structure. The holes 144 may have a size smaller than the wavelength of light in use.

Referring to FIG. 15D, a concave-convex structure 145 may be further provided on the protection layer 140. Owing to the concave-convex structure 145, the roughness of an upper portion of the color conversion structure 300 is greater than the roughness of a lower portion of the color conversion structure 300, and thus, the concave-convex structure 145 may have a guiding function such that the upper and lower portions of the color conversion structure 300 may be guided to intended positions when the color conversion structure 300 is transferred to a transfer substrate. For example, when the color conversion structure 300 is transferred, fluidic self-assembly may be possible owing to the roughness difference between upper and lower surfaces of the color conversion structure 300. The concave-convex structure 145 may include a material having a refractive index different from the refractive index of the protection layer 140, and for example, the concave-convex structure 145 may include a material having a refractive index greater than the refractive index of the protection layer 140.

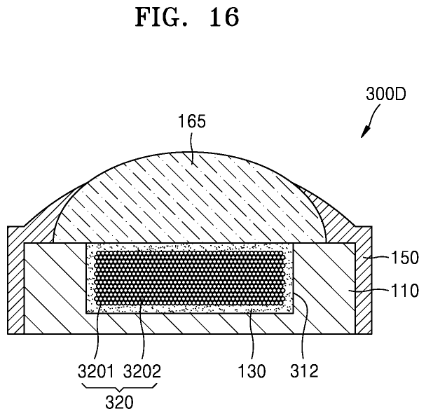

FIG. 16 illustrates an example in which a color conversion structure 300D has a modified protection layer 165 compared with the color conversion structure 300 shown in FIG. 10.

The protection layer 165 of the color conversion structure 300D may have a convex curved surface. The protection layer 165 is provided on an upper portion of a photonic crystal structure 320 and may function like a convex lens.

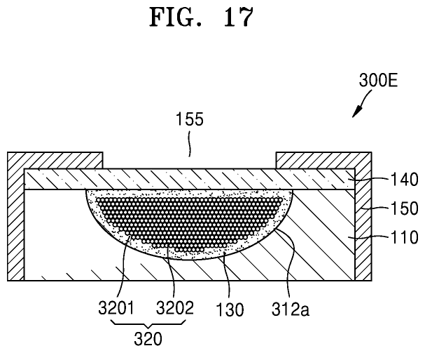

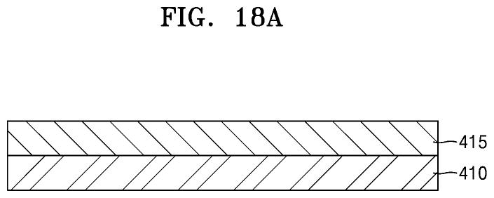

FIG. 17 illustrates an example in which a color conversion structure 300E has a modified groove 312a compared to the color conversion structure 300 shown in FIG. 10. The groove 312a of the color conversion structure 300E may have a curved surface. The groove 312a may have a downwardly-recessed concave shape. A photonic crystal structure 320 may have a hemispherical shape corresponding to the shape of the groove 312a. The direction in which light converted by quantum dots 130 is output from the photonic crystal structure 320 may be adjusted according to the shape of the photonic crystal structure 320.

As described above, according to the one or more of the above example embodiments, the photonic crystal structure of the color conversion structure increases the optical efficiency of the color conversion structure and enables easy adjustment of the thickness of the color conversion structure, and the optical efficiency and transfer efficiency of the color conversion structure may be increased by variously modifying the structure of the protection layer.

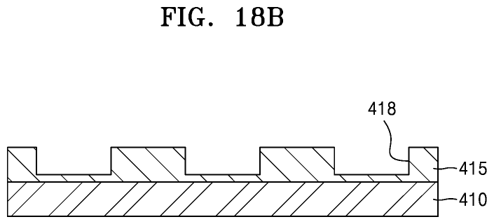

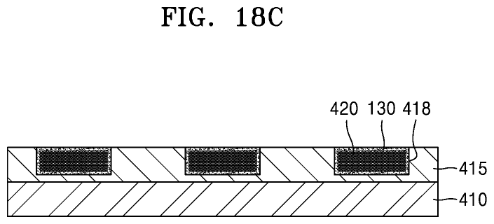

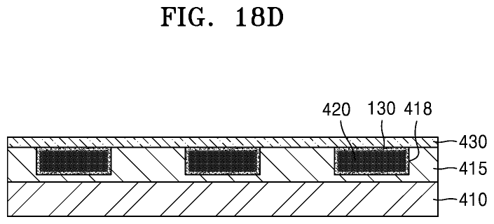

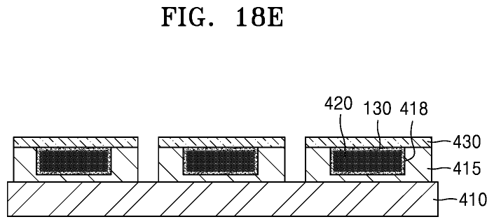

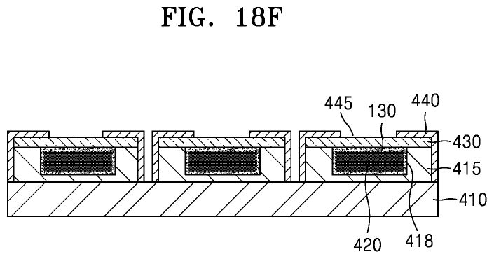

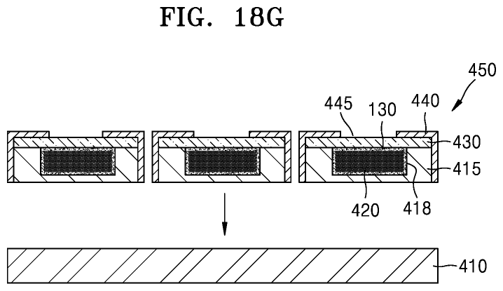

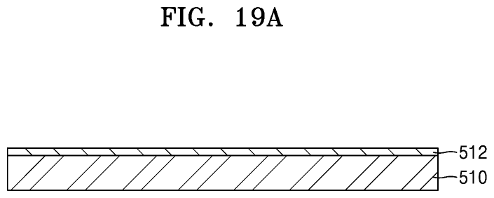

FIGS. 18A to 18G illustrate a method of manufacturing color conversion structures according to an example embodiment.

Referring to FIG. 18A, a base 415 is formed on a substrate 410. The substrate 410 is provided to support the base 415 and is removed later. The substrate 410 may include a sapphire substrate, a glass substrate, or the like. The base 415 may include, for example, GaN, SiO₂, TiO₂, SiN, PMMA, a photoresist, or the like.

Referring to FIG. 18B, grooves 418 are formed by etching the base 415. The base 415 is etched to a depth at which the substrate 410 is not exposed. The depth of the grooves 418 may be determined depending on the thickness of photonic crystal structures to be accommodated in the grooves 418.

Referring to FIG. 18C, photonic crystal structures 420 may be formed in the grooves 418. The photonic crystal structures 420 may be quickly filled in a large area through a spin coating method or a slit coating method. The photonic crystal structures 420 may include quantum dots 130 capable of converting the wavelength of incident light. For example, the photonic crystal structures 420 may include quantum dots 130 capable of emitting green light when excited by blue light, or quantum dots 130 capable of emitting red light when excited by blue light. Various wavelengths may be converted according to the size or material of the quantum dots 130. The photonic crystal structures 420 may include a structure in which the quantum dots 130 are embedded in a porous material for color conversion. The photonic crystal structures 420 may include n-GaN. A porous layer may be formed by depositing n-GaN in the grooves 418 and etching the n-GaN using an electrochemical etching method. Then, the porous layer may be immersed in a quantum dot liquid to embed the quantum dots 130 into the porous layer. The quantum dots 130 embedded in the porous layer may increase scattering of light entering the photonic crystal structure 420, thereby increasing the efficiency of color conversion. The photonic crystal structures 420 may be formed in the grooves 418, and thus the thickness of the photonic crystal structures 420 may be determined by the depth of the grooves 418.

Referring to FIG. 18D, a protection layer 430 may be formed to cover the photonic crystal structures 420 and the base 415. The protection layer 430 may include a light-transmitting material. The protection layer 430 may include, for example, at least one selected from GaN, SiO₂, AL₂O₃, TiO₂, glass, SOG, SiN, and PMMA.

According to an example embodiment, the protection layer 430 may be applied to the photonic crystal structures 420 and the base 415, and may have various structures or shapes. For example, the protection layer 430 may be formed as a distributed Bragg reflection layer by alternately stacking two layers having different refractive indexes. Alternatively, holes (refer to the holes 143 in FIG. 15B or the holes 144 in FIG. 15C) may be formed in the protection layer 430, or a concave-convex structure (refer to the concave-convex structure 145 in FIG. 15D) may be formed on the protection layer 430.

Referring to FIG. 18E, the protection layer 430 and the base 415 are etched between the photonic crystal structures 420 to expose the substrate 410. Accordingly, the base 415 may include bank structures.

Referring to FIG. 18F, a reflection layer 440 is formed on the structure shown in FIG. 18E. Next, window regions 445 are formed by etching regions of the reflection layer 440, which face the photonic crystal structures 420.

Referring to FIG. 18G, a plurality of color conversion structures 450 may be separated by removing the substrate 410 from the base 415. The color conversion structures 450 may include the photonic crystal structures 420 having a given thickness in the bank structures of the base 415. The photonic crystal structures 420 may have a thickness of about 10 μm to about 15 μm. In addition, the photonic crystal structures 420 may be transferred to sub-pixels of a display apparatus.

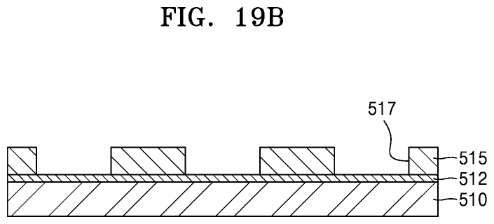

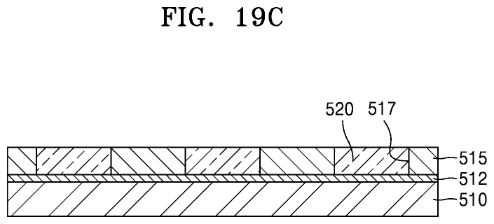

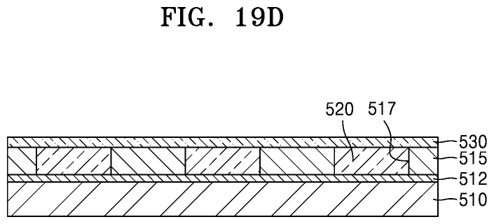

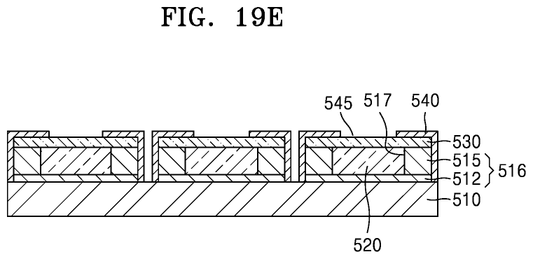

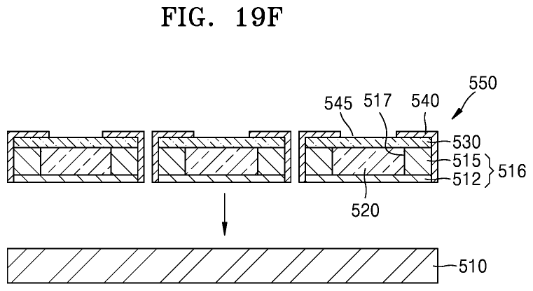

FIGS. 19A to 19F illustrate a method of manufacturing color conversion structures according to another example embodiment.

Referring to FIG. 19A, a first layer 512 is deposited on a substrate 510. For example, the first layer 512 may include a distributed Bragg reflection layer. The first layer 512 may include a structure in which layers of at least two materials selected from SiO₂, TiO₂, ZnO, ZrO, Ta₂O₃, SiN, and AlN are repeatedly arranged. When the first layer 512 includes a distributed Bragg reflection layer, the distributed Bragg reflection layer may be configured to reflect, for example, blue light and transmit red or green light. Alternatively, according to the position of the first layer 512, the distributed Bragg reflection layer may transmit blue light and reflect red or green light. The distributed Bragg reflection layer may have a structure in which a first refractive index layer and a second refractive index layer are alternately stacked as shown in FIG. 15A, and a wavelength to be reflected and a wavelength to be transmitted may be determined by the thicknesses, numbers, and refractive indexes of the first and second refractive index layers.

Referring to FIG. 19B, a second layer 515 may be formed on the first layer 512, and grooves 517 may be formed in the second layer 515 by etching the second layer 515. The second layer 515 may be etched such that the grooves 517 may be formed through the second layer 515 and defined by the first and second layers 512 and 514.

Referring to FIG. 19C, photonic crystal structures 520 are formed in the grooves 517. The photonic crystal structures 520 may have one of the structures described with reference to FIGS. 1, 7, and 8.

Referring to FIG. 19D, a protection layer 530 may be formed to cover the second layer 515 and the photonic crystal structures 520. The protection layer 530 may have various structures as described above.

Referring to FIG. 19E, an isolation operation is performed by etching the protection layer 530, the second layer 515, and the first layer 512 between the photonic crystal structures 520 to expose the substrate 510. In this manner, the first layer 512 and the second layer 515 may be formed as a base 516 having bank structures. Then, a reflection layer 540 is formed on the protection layer 530 and sidewalls of the second layer 515. Next, regions of the reflection layer 540, which face the photonic crystal structures 520, may be etched to form window regions 545.

Referring to FIG. 19F, a plurality of color conversion structures 550 may be separated by removing the substrate 510 from the base 516.

Hereinafter, a method of manufacturing a display apparatus will be described according to an example embodiment.

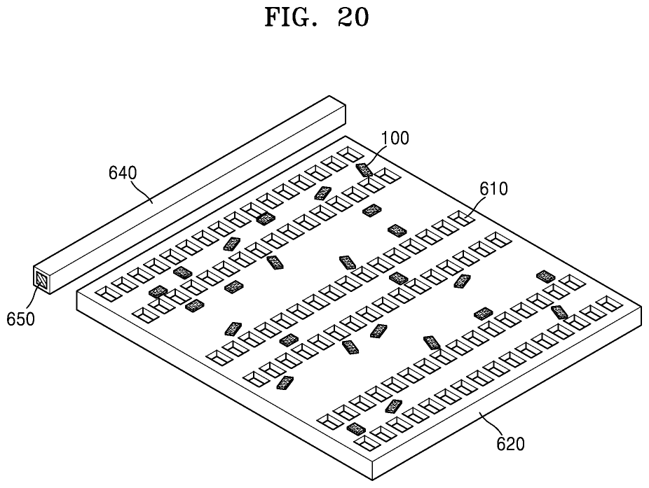

FIG. 20 is a view illustrating a method of transferring color conversion structures by a wet transfer method. Referring to FIG. 20, a transfer substrate 620 may include a plurality of recesses 610 into which color conversion structures 100 are insertable. Here, the color conversion structures 100 may be prepared according to not only the example embodiment shown in FIG. 1 but also other example embodiments. Each of the plurality of recesses 610 may be sized such that at least a portion of a color conversion structure 100 may be inserted into the recess 610. For example, the recesses 610 may have a size in micrometers (μm). For example, the recesses 610 may have a size less than about 1000 μm. For example, the recesses 610 may have a size of about 500 μm or less, about 200 μm or less, or about 100 μm or less. The recesses 610 may be larger than the color conversion structures 100.

According to an example embodiment, a liquid is supplied to the recesses 610. Any type of liquid may be used as long as the liquid does not corrode or damage the color conversion structures 100. The liquid may include, for example, at least one selected from water, ethanol, alcohol, polyols, ketone, halocarbon, acetone, flux, and an organic solvent. The organic solvent may include, for example, isopropyl alcohol (IPA). Examples of the liquid are not limited thereto and may include various other substances.

The liquid may be supplied to the recesses 610 by various methods such as a spray method, a dispensing method, an inkjet-dot method, a method of allowing the liquid to flow on the transfer substrate 620. This will be described later. In addition, the amount of the liquid may be variously adjusted such that the liquid may be exactly filled in the recesses 610 or may overflow the recesses 610.

The color conversion structures 100 are supplied to the transfer substrate 620. The color conversion structures 100 may be directly scattered on the transfer substrate 620 without using any other liquid, or may be supplied to the transfer substrate 620 in a state in which the color conversion structures 100 are contained in a suspension. The suspension containing the color conversion structures 100 may be supplied to the transfer substrate 620 by various methods such as a spray method, a dispensing method in which the suspension is dripped, an inkjet-dot method in which the suspension is ejected as in a printer, or a method in which the suspension is allowed to flow on the transfer substrate 620.

After the liquid is supplied to the transfer substrate 620, the transfer substrate 620 is scanned with an absorber 650 capable of absorbing the liquid. The shape or structure of the absorber 650 is not limited as long as the absorber 650 is capable of absorbing liquid. For example, the absorber 650 may include fabric, tissue, polyester fiber, paper, or a wiper. The absorber 650 may be used alone without using any auxiliary device. However, embodiments are not limited thereto. For example, the absorber 650 may be coupled to a support 640 such that the transfer substrate 620 may be easily scanned with the absorber 650. The support 640 may have various shapes and structures adapted to scan the transfer substrate 620. For example, the support 640 may be shaped like a rod, a blade, a plate, or a wiper. The absorber 650 may be provided on any one surface of the support 640, or may surround the support 640.

The transfer substrate 620 may be scanned with the absorber 650 while being pressed by the absorber 650. The scanning may include an operation in which the absorber 650 absorbs the liquid while the absorber 650 moves over the recesses 610 in contact with the transfer substrate 620. For example, the scanning may be performed by various methods including regular and irregular methods, such as a sliding method, a rotating method, a translating motion method, a reciprocating motion method, a rolling method, a spinning method, and/or a rubbing method. The scanning may be performed by moving the transfer substrate 620 instead of moving the absorber 650, and in this case, methods such as sliding, rotating, translating, reciprocating, rolling, spinning, and/or rubbing may also be used to scan the transfer substrate 620. In addition, it may also be possible to perform the scanning by moving both the absorber 650 and the transfer substrate 620.

The operation of supplying the liquid to the recesses 610 of the transfer substrate 620 and the operation of supplying the color conversion structures 100 to the transfer substrate 620 may be performed in a reversed order. In addition, the operation of supplying the liquid to the recesses 610 of the transfer substrate 620 and the operation of supplying the color conversion structures 100 to the transfer substrate 620 may be simultaneously performed as one operation. For example, the liquid and the color conversion structures 100 may be simultaneously supplied to the transfer substrate 620 by supplying, to the transfer substrate 620, a suspension in which the color conversion structures 100 are contained in the liquid

After the transfer substrate 620 is scanned with the absorber 650, color conversion structures 100 (dummy color conversion structures), which are not inserted into the recesses 610 and remain on the transfer substrate 620, may be removed. Through the operations described above, the color conversion structures 100 may be quickly transferred to the transfer substrate 620.

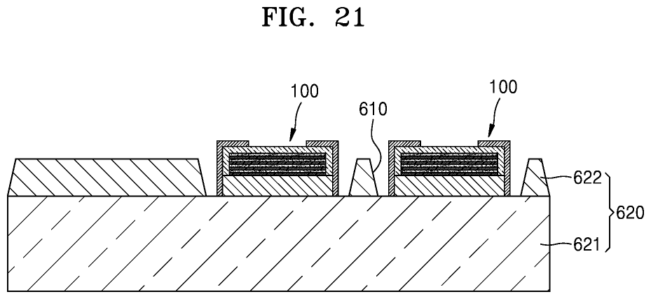

FIG. 21 illustrates an example in which the transfer substrate 620 includes a plurality of layers. For example, the transfer substrate 620 may include a base substrate 621 and a guide mold 622. The base substrate 621 and the guide mold 622 may include different materials or the same material. The color conversion structures 100 are transferred to the recesses 610. Bottom surfaces of bases 110 of the color conversion structures 100 may have roughness less than the roughness of upper surfaces of protection layers 140 or reflection layers 150 of the color conversion structures 100. In this case, when the color conversion structures 100 are transferred to the transfer substrate 620, surfaces of the color conversion structures 100, which have relatively low roughness, may be guided to lower sides of the recesses 610 because of interaction between the liquid and the color conversion structures 100.

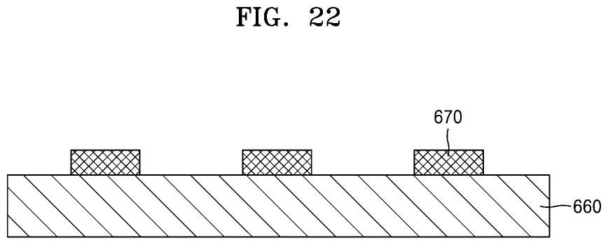

Referring to FIG. 22, micro-semiconductor chips 670 may be arranged on a display substrate 660. The display substrate 660 may be a backplane substrate including a driving unit for driving the micro-semiconductor chips 670, or a transfer mold substrate for transferring the micro-semiconductor chips 670. The micro-semiconductor chips 670 may be arranged on the display substrate 660 by a transfer method. As the transfer method, a pick-and-place method or a fluidic self-assembly method may be used. For example, the micro-semiconductor chips 670 may have a width of about 200 μm or less. The micro-semiconductor chips 670 may be arranged apart from each other in units of sub-pixels.

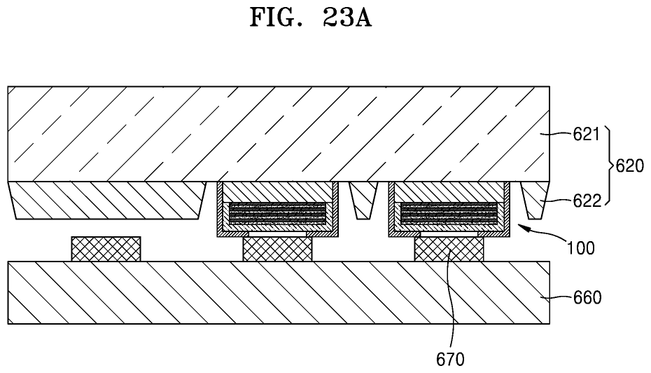

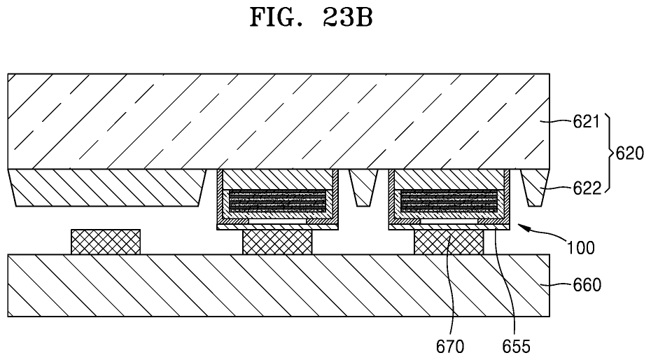

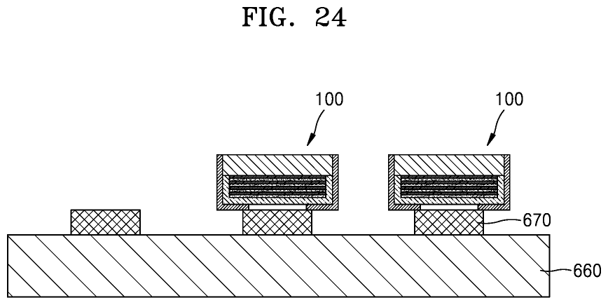

Referring to FIG. 23A, wafer bonding may be performed in a state in which the micro-semiconductor chips 670 face the color conversion structures 100 transferred to the transfer substrate 620 shown in FIG. 21. In addition, referring to FIG. 23B, adhesive layers 655 may be further provided between the color conversion structures 100 and the micro-semiconductor chips 670. The adhesive layers 655 may include a transparent material. Next, referring to FIG. 24, the transfer substrate 620 may be removed. In this manner, the color conversion structures 100 may be coupled to the micro-semiconductor chips 670 in units of wafers.

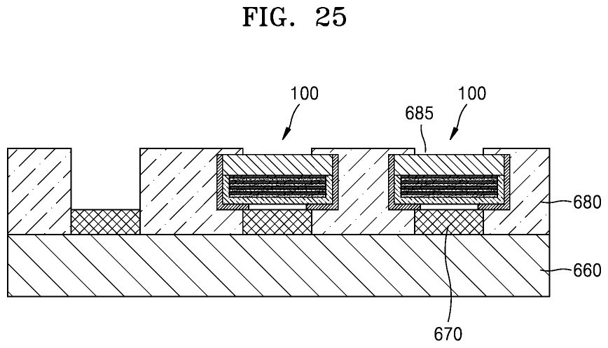

Referring to FIG. 25, a third layer 680 may be formed to cover the color conversion structures 100. The third layer 680 may be an insulating layer. In addition, the third layer 680 may be etched to form window regions 685, which allows light to exit.

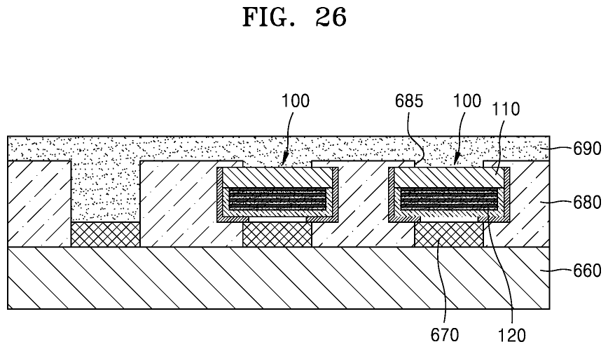

Referring to FIG. 26, a protection layer 690 may be formed on the third layer 680. The protection layer 690 may prevent the color conversion structures 100 from being damaged by external agents. A display apparatus manufactured as described above may operate as follows: when the micro-semiconductor chips 670 emit first-wavelength light to the color conversion structures 100, the color conversion structures 100 may convert the first-wavelength light into second-wavelength light and output the second-wavelength light. For the conversion of first-wavelength light into second-wavelength light, photonic crystal structures 120 of the color conversion structures 100, which include quantum dots 130, are required to have a certain thickness. For example, the photonic crystal structures 120 may have a thickness of about 10 μm to about 15 μm. The thickness of the photonic crystal structures 120 may be maintained owing to the bases 110.

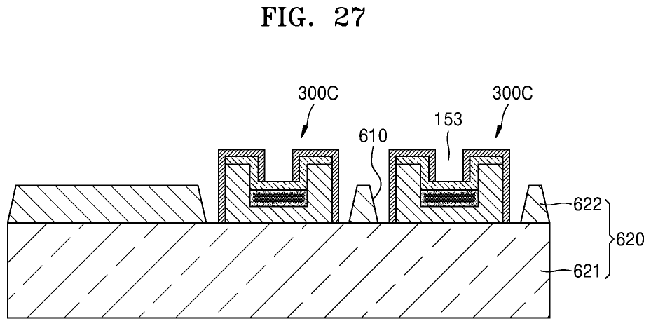

FIG. 27 shows an example in which color conversion structures 300C as shown in FIG. 14 are transferred to the transfer substrate 620. The color conversion structures 300C are transferred to the transfer substrate 620 by the same method as the method described with reference to FIGS. 20 and 21, and thus the method will not be described here.

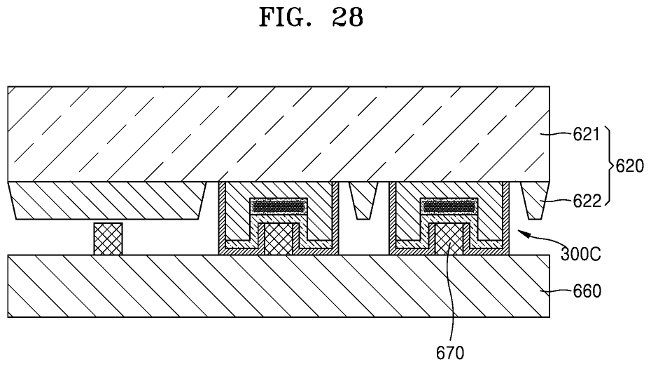

Referring to FIG. 28, the micro-semiconductor chips 670 and the color conversion structures 300C may be coupled to each other in a state in which the color conversion structures 300C face the micro-semiconductor chips 670. The micro-semiconductor chips 670 may be inserted into openings 153 of the color conversion structures 300C. As described above, when the micro-semiconductor chips 670 are inserted into the openings 153, light emitted from the micro-semiconductor chips 670 may not leak sideways, thereby improving optical efficiency.

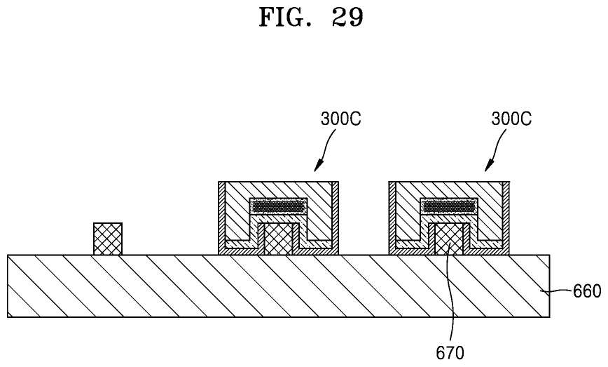

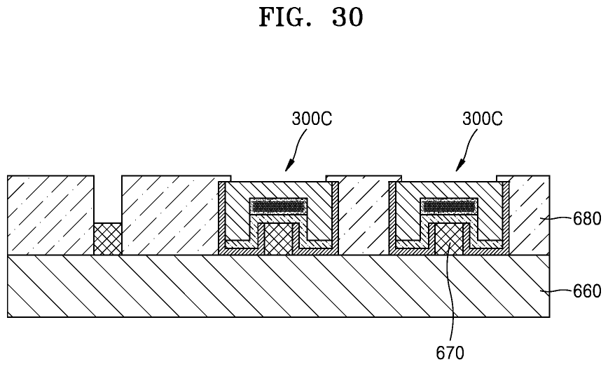

Referring to FIG. 29, the transfer substrate 620 may be removed from the color conversion structures 300C. In addition, referring to FIG. 30, a third layer 680 may be formed between the color conversion structures 300C.

As described above, in the color conversion structures of the example embodiments, the thicknesses of the quantum dots and the photonic crystal structures may be easily guaranteed. In addition, because it is possible to transfer the color conversion structures to a transfer substrate by a wet transfer method, large display apparatuses may be manufactured with high productivity.

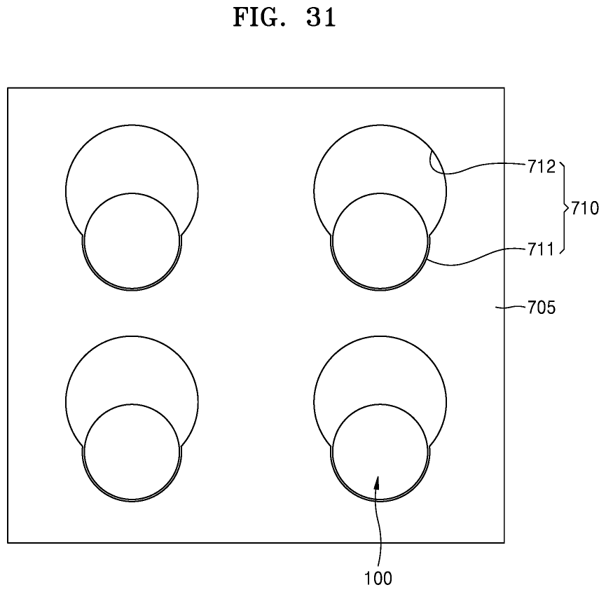

FIG. 31 illustrates a transfer substrate 705, to which the color conversion structures 100 are transferred, according to another example embodiment. The transfer substrate 705 may include recesses 710 configured to receive the color conversion structures 100. The recesses 710 may include first recesses 711 corresponding to the color conversion structures 100, and second recesses 712 that are larger than the first recesses 711 and connected to the first recesses 711. The first recesses 711 may be apart from the centers of the recesses 710 and biased to one side. The first recesses 711 may have, for example, a circular cross-sectional shape, and the second recesses 712 may have a shape overlapping a portion of the circular cross-sectional shape of the first recesses 711.

Because the second recesses 712 are larger than the first recesses 711, the color conversion structures 100 may easily enter the second recess 712 when the color conversion structures 100 are transferred to the transfer substrate 705. As described above, during a scanning operation, the color conversion structures 100 may be pushed into the second recesses 712, and then the color conversion structures 100 may be moved from the second recesses 712 into the first recesses 711 in a scanning direction.

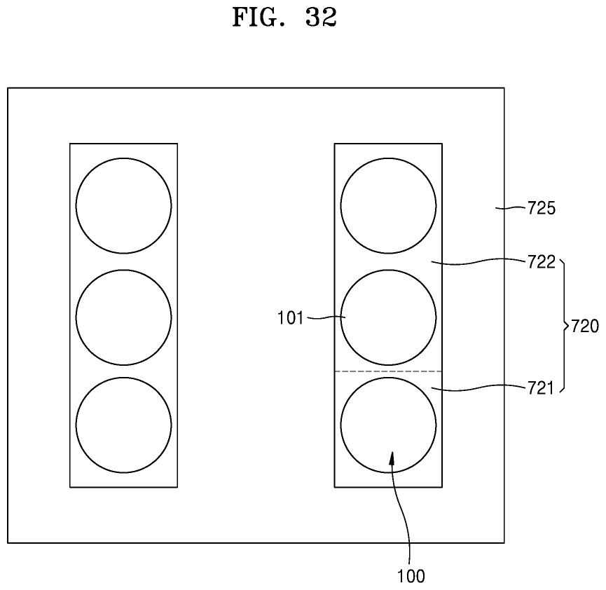

FIG. 32 shows a transfer substrate 725 according to another example embodiment. The transfer substrate 725 is designed to be used multiple times. The transfer substrate 725 may include a plurality of recesses 720, and each of the recesses 720 may accommodate a plurality of color conversion structures 100 and 101. Each of the recesses 720 may include a transfer region 721 for accommodating a color conversion structure 100 to be transferred to a display apparatus; and a reserve region for accommodating color conversion structures 101, which wait for next transfer. The color conversion structure 100 accommodated in the transfer region 721 may be transferred to a display substrate such as the display substrate 660 shown in FIG. 24. Then, a color conversion structure 101 reserved in the reserve region 722 may be moved to the transfer region 721, and the color conversion structure 101 may be transferred from the transfer region 721 to another display substrate. In this manner, the transfer substrate 725 may be used two or more times.

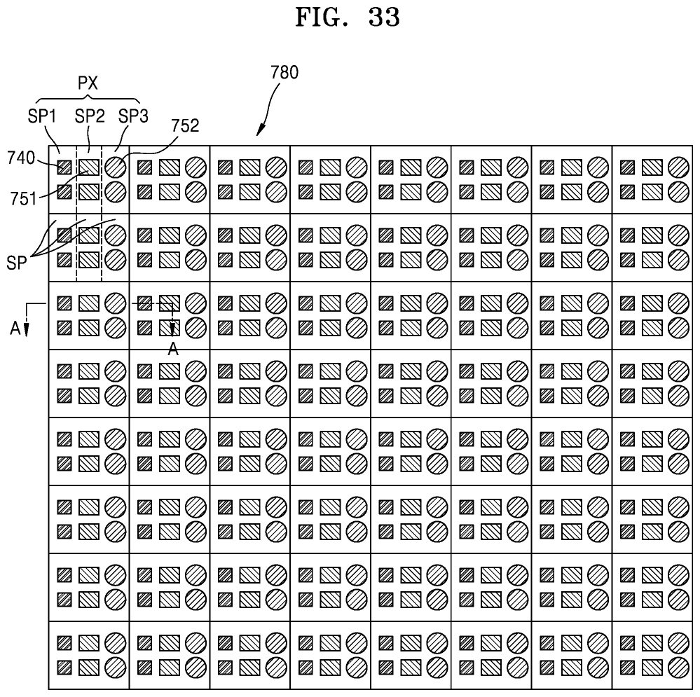

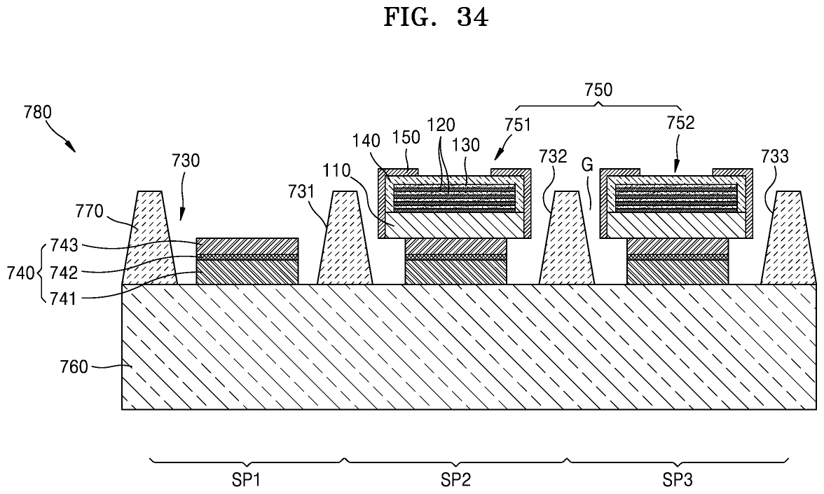

FIG. 33 is a view illustrating a display apparatus 780 according to an example embodiment, and FIG. 34 is a cross-sectional view taken along line A-A of FIG. 33.

Referring to FIG. 33, the display apparatus 780 may include a plurality of pixels PX, and each of the pixels PX may include sub-pixels SP configured to emit different colors. Each of the pixels PX may be one unit for displaying an image. An image may be displayed by controlling the color and amount of light from each of the sub-pixels SP. For example, each of the pixels PX may include a first sub-pixel SP1, a second sub-pixel SP2, and a third sub-pixel SP3.

Referring to FIG. 34, the display apparatus 780 may include a display substrate 760, barrier ribs 770 provided on the display substrate 760, micro-semiconductor chips 740 provided in grooves 730 defined by the barrier ribs 770, and color conversion structures 750 provided on the micro-semiconductor chips 740. The display substrate 760 may include a driving circuit for driving the micro-semiconductor chips 740.

The grooves 730 may include, for example, first grooves 731, second grooves 732, and third grooves 733. The micro-semiconductor chips 740 may be respectively provided in the first grooves 731, the second grooves 732, and the third grooves 733. For example, the micro-semiconductor chips 740 may be micro-light-emitting devices capable of emitting blue light. Each of the micro-semiconductor chips 740 may include a first semiconductor layer 741, a light-emitting layer 742, and a second semiconductor layer 743 that are sequentially stacked. The first semiconductor layer 741 may include a first-type semiconductor. For example, the first semiconductor layer 741 may include an n-type semiconductor. The first semiconductor layer 741 may include a n-type Group III-V semiconductor such as n-GaN. The first semiconductor layer 741 may have a single-layer or multi-layer structure.

The light-emitting layer 742 may be provided on an upper surface of the first semiconductor layer 741. The light-emitting layer 742 may emit light while electrons and holes are combined with each other in the light-emitting layer 742. The light-emitting layer 742 may have a multi-quantum well (MQW) or single-quantum well (SQW) structure. The light-emitting layer 742 may include a Group III-V semiconductor such as GaN.

The second semiconductor layer 743 may be provided on upper surface of the light-emitting layer 742. The second semiconductor layer 743 may include, for example, a p-type semiconductor. The second semiconductor layer 743 may include a p-type Group III-V semiconductor such as p-GaN. The second semiconductor layer 743 may have a single-layer or multi-layer structure. Alternatively, when the first semiconductor layer 741 includes a p-type semiconductor, the second semiconductor layer 743 may include an n-type semiconductor.

The micro-semiconductor chips 740 may be transferred to the display substrate 760. The micro-semiconductor chips 740 may be transferred by a stamp method, a pick-and-place method, or a fluidic self-assembly method. When each of the micro-semiconductor chips 740 is etched or cut in a transferable form, the first semiconductor layer 741, the light-emitting layer 742, and the second semiconductor layer 743 may have the same width.

The color conversion structures 750 may be substantially the same as the color conversion structures 100, 100A, 200, 300, 300A, 300B, 300C, 300D, and 300E described with reference to FIGS. 1 to 17. The color conversion structures 750 shown in FIG. 34 have the same structure as the color conversion structure 100 described with reference to FIG. 1, but any of the color conversion structures 100A, 200, 300, 300A, 300B, 300C, 300D, and 300E described with reference to FIGS. 6 to 17 may be employed as the color conversion structures 750.

The color conversion structures 750 may include: first color conversion structures 751 provided in the second sub-pixels SP2, and second color conversion structures 752 provided in the third sub-pixels SP3. For ease of illustration, the elements of the color conversion structures 750 are denotes with the same reference numerals as the elements of the color conversion structure 100 described with reference to FIG. 1. No color conversion structure may be provided in the first sub-pixels SP1. Quantum dots 130 of photonic crystal structures 120 of the first color conversion structures 751 may emit red light when excited by blue light emitted from the micro-semiconductor chips 740. Quantum dots 130 of photonic crystal structures 120 of the second color conversion structures 752 may emit green light when excited by blue light emitted from the micro-semiconductor chips 740. The wavelength band of emission may vary depending on the material or size of the quantum dots 130 of the photonic crystal structures 120 of the color conversion structures 750.

The width of each of the color conversion structures 750 may be greater than the width of each of the micro-semiconductor chips 740 to increase areas in which the color conversion structures 750 receive light emitted from the micro-semiconductor chips 740. In the current embodiment, the color conversion structures 750 may be transferred to upper portions of the micro-semiconductor chips 740 by the wet transfer method described above. In this case, the micro-semiconductor chips 740 may face bases 110 of the color conversion structures 750. In addition, when the color conversion structures 750 are transferred onto the micro-semiconductor chips 740, the positions of the color conversion structures 750 in the grooves 730 may be irregular. Therefore, the positions of the color conversion structures 750 relative to the micro-semiconductor chips 740 may be different in the sub-pixels SP. The width of each of the color conversion structures 750 is greater than the width of each of the micro-semiconductor chips 740 such that even when the transfer positions of the color conversion structures 750 vary, the areas in which light emitted from the micro-semiconductor chips 740 are to be received may be as wide as possible.

The color conversion structures 750 may be apart from the barrier ribs 770. The color conversion structures 750 are transferred into the grooves 730 and arranged in the grooves 730. That is, the grooves 730 are not fully filled with the color conversion structures 750, and thus there may be gaps G between the barrier ribs 720 and the color conversion structures 750.

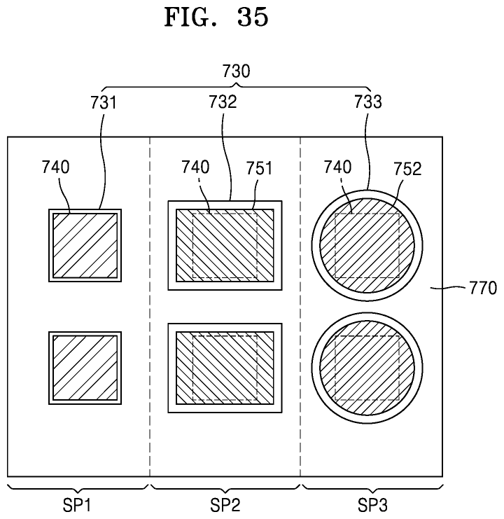

FIG. 35 is a plan view illustrating the configuration shown in FIG. 34. FIG. 35 illustrates one pixel PX which may include a first sub-pixel SP1, a second sub-pixel SP2, and a third sub-pixel SP3.

A plurality of grooves 730 may be defined by barrier ribs 720. The plurality of grooves 730 may include, for example, first grooves 731 provided in the first sub-pixel SP1, second grooves 732 provided in the second sub-pixel SP2, and third grooves 733 provided in the third sub-pixel SP3. One or a plurality of grooves 730 may be provided in each sub-pixel SP. In addition, the plurality of grooves 730 may have different cross-sectional shapes or sizes depending on the sub-pixels SP. The size of each of the plurality of grooves 730 may refer to the area or width of a cross-section of each of the plurality of grooves 730. For example, the first grooves 731 may have a tetragonal cross-sectional shape, the second grooves 732 may have a larger tetragonal cross-sectional shape than the first groove 731, and the third grooves 733 may have a circular cross-sectional shape. In addition, the color conversion structures 750 may have shapes or sizes corresponding to the shapes or sizes of the plurality of grooves 730. For example, the first color conversion structures 751 may have a tetragonal cross-sectional shape corresponding to the second grooves 732, and the second color conversion structures 752 may have a circular cross-sectional shape corresponding to the third grooves 733.

As described above, the cross-sectional shapes or sizes of the grooves 730 and the color conversion structures 750 are different according to the sub-pixels SP such that when the color conversion structures 750 are transferred into the grooves 730, the color conversion structures 750 may be positioned in desired sub-pixels SP. When the first grooves 731 are smallest and the cross-sectional shapes of the second groove 732 and the third groove 733 are different from each other, the first color conversion structures 751 and the second color conversion structures 752 may be simultaneously transferred. For example, the cross-sectional shape of the first grooves 731 is not limited as long as the first grooves 731 have a size which does not allow the first color conversion structures 751 and the second color conversion structures 752 to enter the first grooves 731. In addition, the second grooves 732 may have a size or cross-sectional shape not allowing the second color conversion structures 752 to enter the second grooves 732, and the third grooves 733 may have a size or a cross-sectional shape not allowing the first color conversion structures 751 to enter the third grooves 733.

Alternatively, the grooves 730 may have the same shape but the sizes of the grooves 730 may be different from each other. For example, the first grooves 731, the second grooves 732, and the third grooves 733 may each have a tetragonal cross-sectional shape with a relationship of the width (or size) of the first grooves 731<the width (or size) of the second grooves 732<the width (or size) of the third grooves 733 and a relationship of the width (or size) of the first color conversion structures 751<the width (or size) of the second color conversion structures 752. In this case, the first color conversion structures 751 and the second color conversion structures 752 may be sequentially transferred. The second color conversion structures 752 having the largest size may be first transferred to the third grooves 733, and then the first color conversion structures 751 may be transferred to the second grooves 732.

The shapes and sizes of the first grooves 731, the second grooves 732, the third grooves 733, the first color conversion structures 751, and the second color conversion structures 752 are appropriately selected such that the first color conversion structures 751 and the second color conversion structures 752 may be simultaneously or sequentially transferred into the grooves 730 corresponding thereto.

In addition, although the number of grooves in each sub-pixel SP may vary, FIG. 35 shows an example in which two grooves are provided in each sub-pixel SP.

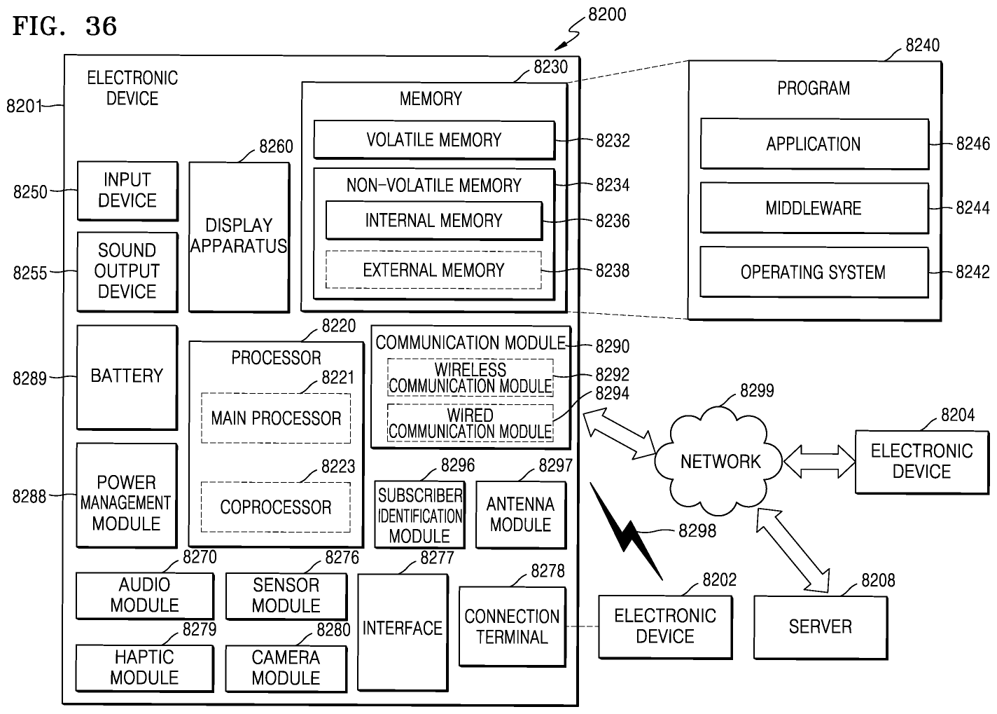

FIG. 36 is a block diagram illustrating an electronic device 8201 including a display apparatus 8260 according to an example embodiment.

Referring to FIG. 36, the electronic device 8201 may be provided in a network environment 8200. In the network environment 8200, the electronic device 8201 may communicate with another electronic device 8202 through a first network 8298 (such as a short-range wireless communication network) or may communicate with another electronic device 8204 and/or a server 8208 through a second network 8299 (such as a long-range wireless communication network). The electronic device 8201 may communicate with the electronic device 8204 through the server 8208. The electronic device 8201 may include a processor 8220, a memory 8230, an input device 8250, a sound output device 8255, the display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the components of the electronic device 8201 may be omitted, or other components may be added to the electronic device 8201. Some of the components may be implemented as one integrated circuit. For example, the sensor module 8276 (such as a fingerprint sensor, an iris sensor, or an illuminance sensor) may be embedded in the display apparatus 8260 (such as a display).

The processor 8220 may execute software (such as a program 8240) to control one or more other components (such as hardware or software components) of the electronic device 8201 which are connected to the processor 8220, and the processor 8220 may perform various data processing or operations. As part of data processing or computation, the processor 8220 may load commands and/or data received from other components (such as the sensor module 8276, the communication module 8290, etc.) on a volatile memory 8232, process the commands and/or data stored in the volatile memory 8232, and store resulting data in a non-volatile memory 8234. The non-volatile memory 8234 may include an internal memory 8236 and an external memory 8238. The processor 8220 may include: a main processor 8221 (such as a central processing unit, an application processor, etc.); and a coprocessor 8223 (such as a graphics processing unit, an image signal processor, a sensor hub processor, a communication processor, etc.) that may be operated independently or in conjunction with the main processor 8221. The coprocessor 8223 may consume less power than the main processor 8221 and may perform a specialized function.

The coprocessor 8223 may control functions and/or states related to some of the components (such as the display apparatus 8260, the sensor module 8276, and the communication module 8290) of the electronic device 8201, instead of the main processor 8221 while the main processor 8221 is in an inactive state (sleep mode) or together with the main processor 8221 while the main processor 8221 is in an active state (application-execution mode). The coprocessor 8223 (such as an image signal processor, a communication processor, etc.) may be implemented as part of a functionally related component (such as the camera module 8280 or the communication module 8290).

The memory 8230 may store various pieces of data required by the components (such as the processor 8220, the sensor module 8276, etc.) of the electronic device 8201. For example, the data may include: software (such as the program 8240); and instruction input data and/or output data which are related to the software. The memory 8230 may include the volatile memory 8232 and/or the non-volatile memory 8234.

The program 8240 may be stored as software in the memory 8230 and may include an operating system 8242, middleware 8244, and/or an application 8246.

The input device 8250 may receive, from outside the electronic device 8201 (for example, a user), commands and/or data to be used in the components (such as the processor 8220) of the electronic device 8201. The input device 8250 may include a remote controller, a microphone, a mouse, a keyboard, and/or a digital pen (such as a stylus pen).

The sound output device 8255 may output a sound signal to the outside of the electronic device 8201. The sound output device 8255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display apparatus 8260 may provide information to the outside of the electronic device 8201 in a visual manner. The display apparatus 8260 may include a device such as a display, a hologram device, or a projector, and a control circuit for controlling the device. The display apparatus 8260 may include any of the display apparatuses described with reference to FIGS. 1 to 35. The display apparatus 8260 may include: touch circuitry configured to detect touches; and/or a sensor circuit (such as a pressure sensor) configured to measure the magnitudes of forces generated by touches.

The audio module 8270 may convert a sound into an electric signal or may conversely convert an electric signal into a sound. The audio module 8270 may acquire a sound through the input device 8250, or may output a sound through the sound output device 8255 and/or the speaker and/or headphone of another electronic device (such as the electronic device 8202) which are directly or wirelessly connected to the electronic device 8201.

The sensor module 8276 may detect an operating state (such as the power or the temperature) of the electronic device 8201 or an external environmental state (such as a user state) and may generate an electrical signal and/or a data value corresponding to the detected state. The sensor module 8276 may include a gesture sensor, a gyro sensor, a barometric pressure sensor, a magnetic sensor, an accelerometer sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols that may be used by the electronic device 8201 for directly or wirelessly connection with another electronic device (such as the electronic device 8202). The interface 8277 may include a high-definition multimedia Interface (HDMI), a universal serial bus (USB) interface, a secure digital (SD) card interface, and/or an audio interface.

A connection terminal 8278 may include a connector through which the electronic device 8201 may be physically connected to another electronic device (such as the electronic device 8202). The connection terminal 8278 may include an HDMI connector, an USB connector, an SD card connector, and/or an audio connector (such as a headphone connector).

The haptic module 8279 may convert an electrical signal into a mechanical stimulus (such as vibration, movement, etc.) or an electrical stimulus that a user may perceive by the tactile or kinesthetic sense. The haptic module 8279 may include a motor, a piezoelectric element, and/or an electrical stimulation device.

The camera module 8280 may capture still images and moving images. The camera module 8280 may include a lens assembly including one or more lenses, image sensors, image signal processors, and/or flashes. The lens assembly of the camera module 8280 may focus light coming from a subject to be imaged.

The power management module 8288 may manage power supplied to the electronic device 8201. The power management module 8388 may be implemented as part of a power management integrated circuit (PMIC).

The battery 8289 may supply power to the components of the electronic device 8201. The battery 8289 may include non-rechargeable primary cells, rechargeable secondary cells, and/or fuel cells.

The communication module 8290 may support the establishment of a direct (wired) communication channel and/or a wireless communication channel between the electronic device 8201 and another electronic device (such as the electronic device 8202, the electronic device 8204, or the server 8208), and may support communication through the established communication channel. The communication module 8290 may include one or more communication processors that operate independently of the processor 8220 (such as an application processor) and support direct communication and/or wireless communication. The communication module 8290 may include: a wireless communication module 8292 (such as a cellular communication module, a short-range wireless communication module, or a global navigation satellite system (GNSS) communication module); and/or a wired communication module 8294 (such as a local area network (LAN) communication module or a power line communication module). The communication modules 8282 and 8294 may communicate with another electronic device through the first network 8298 (for example, a short-range communication network such as Bluetooth, WiFi direct, or infrared data association (IrDA)), or the second network 8299 (for example, a long-range communication network such as a cellular network, the Internet, or a computer network (LAN, WAN, etc.)). Such various types of communication modules may be integrated into one component (single chip, etc.) or may be implemented as a plurality of components (plural chips) separate from each other. The wireless communication module 8292 may identify and authenticate the electronic device 8201 in a communication network such as the first network 8298 and/or the second network 8299 by using subscriber information (such as an international mobile subscriber identifier (IMSI)) stored in the subscriber identification module 8296.

The antenna module 8297 may transmit or receive signals and/or power to or from the outside (for example, other electronic devices). An antenna may include a radiator which has a conductive pattern formed on a substrate (such as a PCB). The antenna module 8297 may include one or a plurality of such antennas. When the antenna module 8297 include a plurality of antennas, the communication module 8290 may select one of the plurality of antennas which is suitable for a communication method used in a communication network such as the first network 8298 and/or the second network 8299. Signals and/or power may be transmitted between the communication module 8290 and another electronic device through the selected antenna. In addition to the antennas, other components (such as a radio-frequency integrated circuit (RFIC)) may be included as part of the antenna module 8297.

Some of the components may be connected to each other and exchange signals (such as commands or data) by an inter-peripheral communication scheme (such as a bus, general purpose input and output (GPIO), serial peripheral interface (SPI), or mobile industry processor interface (MIPI)).

Commands or data may be transmitted between the electronic device 8201 and the (external) electronic device 8204 through the server 8208 connected to the second network 8299. The other electronic devices 8202 and 8204 and the electronic device 8201 may be the same type of electronic device or may be different types of electronic devices. All or some of operations of the electronic device 8201 may be executed in one or more of the other electronic devices 8202 and 8204, and the server 8208. For example, when the electronic device 8201 needs to perform a certain function or service, the electronic device 8201 may request one or more other electronic devices to perform a part or all of the function or service instead of performing the function or service by itself. The one or more other electronic devices receiving the request may perform an additional function or service related to the request, and may transmit results thereof to the electronic device 8201. To this end, cloud computing, distributed computing, and/or client-server computing techniques may be used.

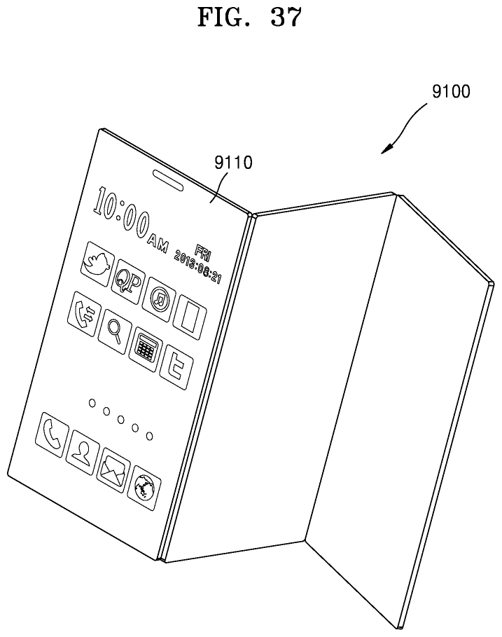

FIG. 37 is a view illustrating an example in which an electronic device is applied to a mobile device 9100 according to an example embodiment. The mobile device 9100 may include a display apparatus 9110, and the display apparatus 9110 may include any of the display apparatuses described with reference to FIGS. 1 to 35. The display apparatus 9110 may have a foldable structure such as a multi-foldable structure.

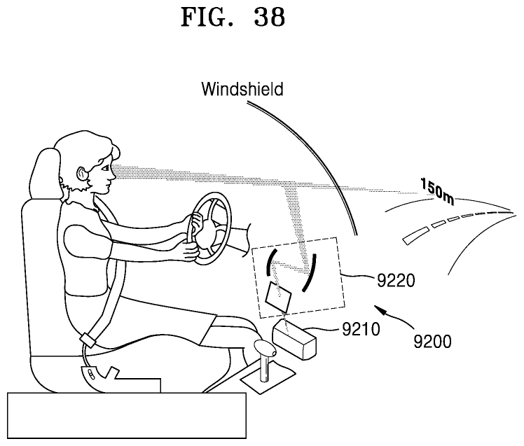

FIG. 38 is a view illustrating an example in which a display apparatus is applied to a vehicle according to an example embodiment. The display apparatus may be a vehicular head-up display apparatus 9200, and may include: a display 9210 provided in an region of the vehicle; and an optical path changing member 9220 configured to change the optical path of light such that a driver may see images generated by the display 9210.

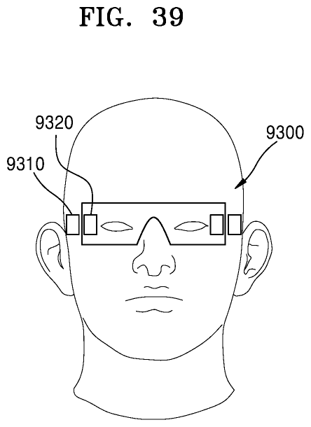

FIG. 39 is a view illustrating an example in which a display apparatus is applied to augmented reality glasses or virtual reality glasses according to an example embodiment. The augmented reality glasses 9300 may include: a projection system 9310 configured to form images; and elements 9320 configured to guide the images from projection system 9310 into the eyes of a user. The projection system 9310 may include any of the display apparatuses described with reference to FIGS. 1 to 35.

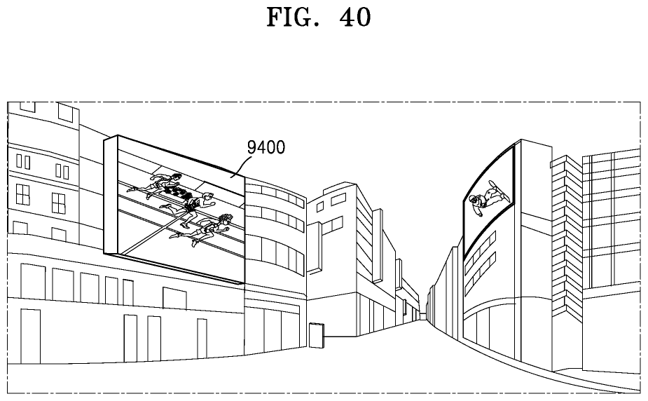

FIG. 40 is a view illustrating an example in which a display apparatus is applied to large signage 9400 according to an example embodiment. The signage 9400 may be used for outdoor advertisement using a digital information display and may control advertisement content and the like through a communication network. For example, the signage 9400 may be implemented through the electronic device 8201 described with reference to FIG. 36.

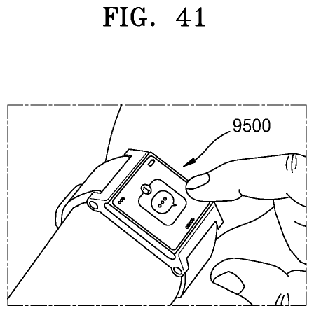

FIG. 41 is a view illustrating an example in which a display apparatus is applied to a wearable display 9500 according to an example embodiment. The wearable display 9500 may include any of the display apparatuses described with reference to FIGS. 1 to 35 and may be implemented through the electronic device 8201 described with reference to FIG. 36.

The display apparatuses of the example embodiments may be applied to various products such as a rollable TV and a stretchable display.

As described above, according to the one or more of the above example embodiments, the color conversion structures may be efficiently transferred to display apparatuses, which operate using micro-semiconductor chips. The color converting structures may be transferred to a substrate by a fluidic self-assembly method.

According to the one or more of the above example embodiments, the display apparatuses may efficiently display color images by using the color conversion structures. According to the one or more of the above example embodiments, transferable color conversion structures may be easily manufactured by the color conversion structure manufacturing methods.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A color conversion structure comprising:
a base;
a photonic crystal structure on the base; and
a plurality of quantum dots provided in the photonic crystal structure.

2. The color conversion structure of claim 1, wherein the base comprises a bank structure comprising a groove, and the photonic crystal structure is provided in the groove.

3. The color conversion structure of claim 1, wherein the color conversion structure is configured in units of pixels and is transferrable.

4. The color conversion structure of claim 1, further comprises a protection layer on the photonic crystal structure.

5. The color conversion structure of claim 4, wherein the protection layer comprises a concave-convex structure.

6. The color conversion structure of claim 1, further comprises a distributed Bragg reflection layer on the photonic crystal structure.

7. The color conversion structure of claim 2, further comprises a distributed Bragg reflection layer on a bottom of the groove.

8. The color conversion structure of claim 2, wherein the photonic crystal structure has a thickness less than a depth of the groove.

9. The color conversion structure of claim 1, wherein the photonic crystal structure has a thickness of about 10 μm to about 15 μm.

10. The color conversion structure of claim 1, wherein the photonic crystal structure comprises a stacked structure in which two or more material layers having different refractive indexes are alternately arranged.

11. The color conversion structure of claim 1, wherein the base comprises a groove array having a grating shape, and the photonic crystal structure is provided in the groove array.

12. The color conversion structure of claim 1, wherein the base comprises a groove, and
wherein the photonic crystal structure comprises:
a first material layer provided in the groove; and
a plurality of second material portions that are three-dimensionally arranged in the first material layer.

13. The color conversion structure of claim 12, wherein the first material layer comprises a porous material, and the plurality of quantum dots are provided in the porous material.

14. The color conversion structure of claim 13, wherein the porous material comprises nGaN.

15. The color conversion structure of claim 1, further comprises a reflection layer on a lateral portion of the photonic crystal structure.

16. The color conversion structure of claim 1, further comprises a window region provided on a surface of the photonic crystal structure, the window region configured to allow light to be incident on the photonic crystal structure.

17. The color conversion structure of claim 1, further comprises a lens array provided on a surface of the photonic crystal structure, the lens array being configured to focus light on to the photonic crystal structure.

18. A display apparatus comprising:
a display substrate;
a plurality of micro-semiconductor chips provided on the display substrate and spaced apart from each other; and
a plurality of color conversion structures on the plurality of micro-semiconductor chips,
wherein each of the color conversion structures comprises:
a base,
a photonic crystal structure on the base, and
a plurality of quantum dots provided in the photonic crystal structure.

19. The display apparatus of claim 18, wherein each of the plurality of photonic crystal structures are adjacent to a respective one of the plurality micro-semiconductor chips and face the respective one of the plurality micro-semiconductor chips.

20. The display apparatus of claim 18, wherein each of the plurality of bases comprises a bank structure comprising a groove, and each of the plurality of photonic crystal structures is provided in the groove.

21. The display apparatus of claim 20, wherein the plurality of color conversion structures are configured in units of pixels and are transferrable.

22. The display apparatus of claim 18, wherein each of the color conversion structures further comprises a protection layer on each of the plurality of photonic crystal structures.

23. The display apparatus of claim 18, wherein each of the plurality of photonic crystal structures have a thickness of about 10 μm to about 15 μm.

24. The display apparatus of claim 18, wherein each of the plurality of photonic crystal structures comprises a stacked structure in which two or more material layers having different refractive indexes are alternately arranged.

25. The display apparatus of claim 18, wherein each of the plurality of bases comprises a groove array having a grating shape, and each of the plurality of photonic crystal structures is provided in the groove array.

26. The display apparatus of claim 18, wherein each of the plurality of bases comprises a groove, and
wherein each of the plurality of photonic crystal structures comprises:
a first material layer provided in the groove; and
a plurality of second material portions that are three-dimensionally provided in the first material layer.

27. The display apparatus of claim 26, wherein each of the plurality of first material layers comprises a porous material, and the plurality of quantum dots are provided in the porous material.

28. The display apparatus of claim 18, wherein each of the color conversion structures further a reflection layer on a lateral portion of each of the photonic crystal structures.

29. The display apparatus of claim 18, wherein each of the color conversion structures further comprises a lens array provided on a surface of each of the photonic crystal structures, the lens array being configured to collect light.

30. A method of manufacturing a color conversion structure, the method comprising:
forming a base on a substrate;
forming a photonic crystal structure on the base;
forming a plurality of quantum dots in the photonic crystal structure;
etching the base and the photonic crystal structure in units of pixels; and
removing the substrate.

31. The method of claim 30, further comprises forming a protection layer on the photonic crystal structure.

32. The method of claim 30, further comprises forming a reflection layer on a sidewall of the photonic crystal structure.

33. The method of claim 30, wherein the forming the base comprises:
forming a groove on a bank structure, and
providing the photonic crystal structure is in the groove.

34. The method of claim 30, wherein the forming the photonic crystal structure comprises forming a stacked structure by alternately arranging two or more material layers having different refractive indexes.

35. The method of claim 30, wherein the forming the photonic crystal structure comprises:
forming a groove array having a grating shape in the base, and
providing the photonic crystal structure is in the groove array.

36. The method of claim 30, wherein the forming the photonic crystal structure comprises:
forming a groove in the base,
providing a first material layer in the groove; and
providing a plurality second material portions that are three-dimensionally arranged in the first material layer.

37. The method of claim 36, wherein the first material layer comprises a porous material, and the plurality quantum dots are provided in the porous material.

38. The method of claim 30, further comprises providing a lens array on a surface of the photonic crystal structure, the lens array configured to focus light on the photonic crystal structure.
